(19) United States
(12) Patent Application Publication
(10) Pub. No.: US 2023/0411231 A1
(43) Pub. Date: Dec. 21, 2023

(54) FAN-OUT TYPE PACKAGING STRUCTURE

(71) Applicant: WaferChem Technology Corporation, Miaoli County (TW)

(72) Inventors: Chih-Lung YU, Miaoli County (TW); Pin-Sheng WANG, Miaoli County (TW); Yan-Chiuan LIOU, Miaoli County (TW); Yu-Chuan LIU, Miaoli County (TW); Yu-Chi LIN, Miaoli County (TW); Teng-Kuei CHEN, Miaoli County (TW)

(21) Appl. No.: 18/208,791

(22) Filed: Jun. 12, 2023

(30) Foreign Application Priority Data
Jun. 15, 2022 (TW) 111206301

(51) Int. Cl. H01L 23/31; H01L 23/29; H01L 25/065; H01L 21/56

(52) U.S. Cl. CPC H01L 23/3135; H01L 23/293; H01L 23/3128; H01L 25/0655; H01L 21/568

(57) ABSTRACT

A fan-out type packaging structure includes a strain adjustment layer, a plurality of chips, an encapsulation layer, a redistribution layer, and a plurality of solder balls. The strain adjustment layer is made of a polymer material and has at least 95% laser absorbance. The plurality of chips are partially embedded in the strain adjustment layer and are spaced apart from each other. The encapsulation layer surrounds the chips and is connected to the strain adjustment layer. The redistribution layer covers the encapsulation layer and the chips. The plurality of solder balls are disposed on the redistribution layer and are spaced apart from each other.

### CROSS-REFERENCE TO RELATED APPLICATION

This application claims priority to Taiwanese Utility Model Patent Application No. 111206301, filed on Jun. 15, 2022.

### FIELD

The disclosure relates to a packaging structure, and more particularly to a fan-out type packaging structure.

### BACKGROUND

Electronics components have been shrinking in size due to the demand for better efficiency and higher computational power. As electronic components decrease in size, the circuitry of the electronic components must also be miniaturized. Therefore, effective utilization of space on each wafer has become an important topic for electronic component manufacturers. One way of increasing effective utilization of the wafer is to use a fan-out type packaging process to fabricate the electronic component.

Referring to FIG. 1, a conventional fan-out type packaging structure includes a back protection layer 11, a plurality of chips 12, an encapsulation layer 13, a redistribution layer 14, and a plurality of solder balls 15. The back protection layer 11 has a thickness that is between 20 μm and 30 μm. The plurality of chips 12 are spaced apart from each other and disposed on the back protection layer 11. The encapsulation layer 13 surrounds each of the chips 12. The redistribution layer 14 is formed on the chips 12 and the encapsulation layer 13. The plurality of solder balls 15 are disposed on the redistribution layer 14. FIGS. 2 to 4 show steps (A) to (J) of a method of making the conventional fan-out type packaging.

Referring to FIG. 2, in step (A), a glass base plate 100 is provided. In step (B), the glass base plate 100 is laminated with a laser-debond film 101 with a thickness ranging from 5 μm to 10 μm. Next, in step (C), the plurality of chips 12 are die-attached to the laser-debond film 101.

Referring to FIG. 3, the method proceeds to step (D) in which an encapsulation material 130 is compression molded to cover the chips 12. In step (E), the encapsulation material 130 is ground to expose a top surface of each chip 12, and thereby forming the encapsulation material 130 into the encapsulation layer 13. Next, in a step (F), a metal layer 140 is formed on the encapsulation layer 13 and the exposed top surface of each chip 12.

Referring to FIG. 4, the method progresses to step (G) where the metal layer 140 is patterned via photolithography and etching, thereby patterning the metal layer 140 into the redistribution layer 14. In step (H), the plurality of solder balls 15 are disposed on the redistribution layer 14. Subsequently, in a step (I), a laser (not shown) is used to debond the laser-debond film 101. This causes the glass base plate 100 to separate from a bottom surface of each chip 12 and from a bottom surface of the encapsulation layer 13. Next, in step (J), the back protection layer 11 is adhered to the bottom surface of each chip 12 and the bottom surface of the encapsulation layer 13, and thus the method for fabricating the fan-out type packaging structure shown in FIG. 1 is completed. It is worth noting that the back protection layer 11 adhering to the chips 12 and the encapsulation layer 13 in the step (J) prevents warpage of the chips 12 and the encapsulation layer 13 which is a usually occurs after the laser debonding step (I). However, even though the back protection layer 11 may help reduce the amount of warpage, when the degree of warpage is too severe, adhering the back protection layer 11 to the bottom surface of each chip 12 and the bottom surface of the encapsulation layer 12 will not be able to effectively curtail the warpage. Therefore, warpage should be identified as a factor that effects fabrication yield rates, and how to effectively solve warpage and prevent warpage from occurring after the laser debonding step so that fabrication yield rates can be improved is one of the foremost problems confronting the technical field.

### SUMMARY

Therefore, an object of the disclosure is to provide a fan-out type packaging structure that can alleviate at least one of the drawbacks of the prior art.

According to the disclosure, the fan-out type packaging structure includes a strain adjustment layer, a plurality of chips, an encapsulation layer, a redistribution layer, and a plurality of solder balls. The strain adjustment layer is made of a polymer material and has at least 95% laser absorbance. The plurality of chips are partially embedded in the strain adjustment layer and are spaced apart from each other. The encapsulation layer surrounds the chips and is connected to the strain adjustment layer. The redistribution layer covers the encapsulation layer and the chips. The plurality of solder balls are disposed on the redistribution layer and are spaced apart from each other.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a conventional fan-out type packaging structure.

FIGS. 2 to 4 are schematic cross-sectional views illustrating steps in a method of fabricating the conventional fan-out type packaging structure.

FIG. 5 is a schematic cross-sectional view illustrating an embodiment of a fan-out type packaging structure according to the present disclosure.

FIGS. 6 to 8 are schematic cross-sectional views illustrating steps in a method of fabricating the embodiment of the fan-out type packaging structure according to the present disclosure.

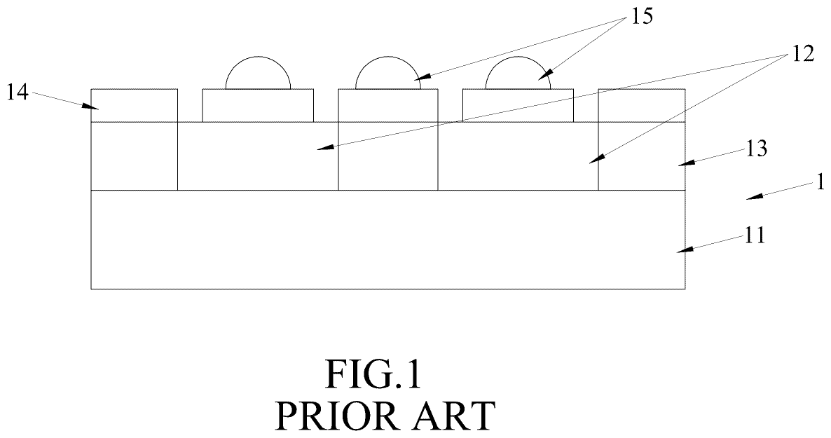

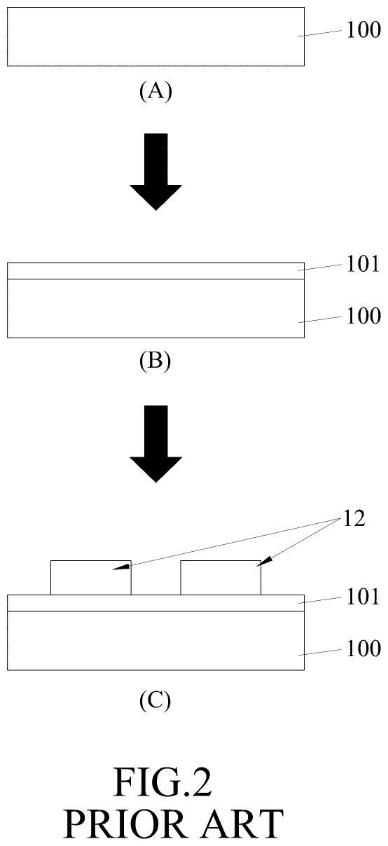

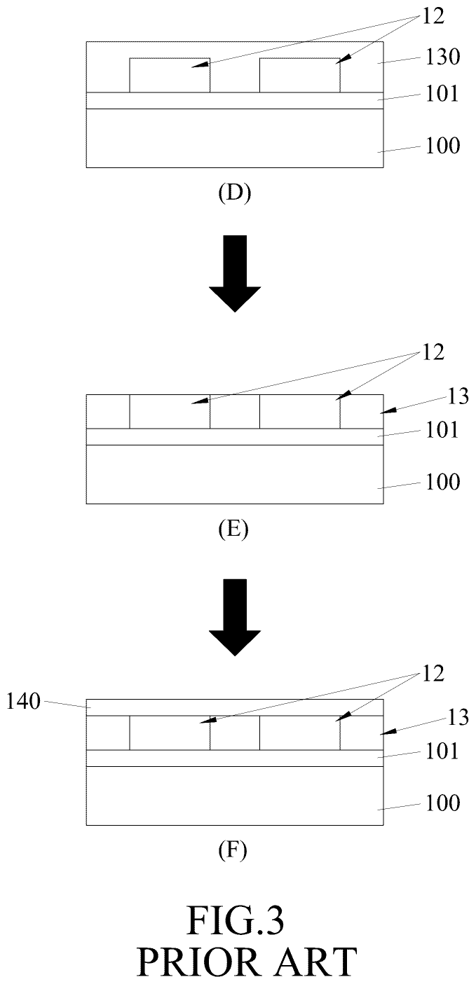

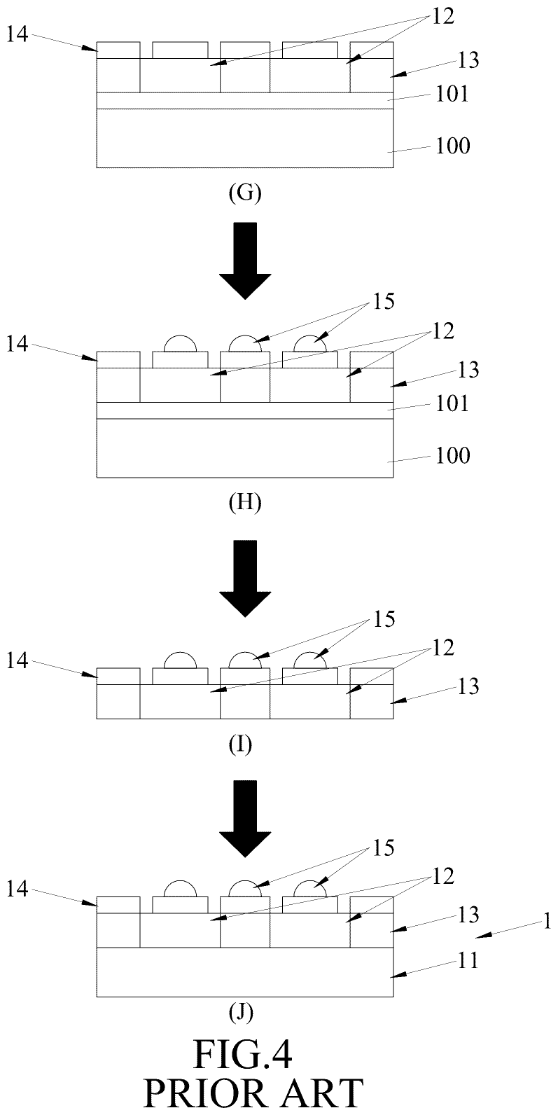

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

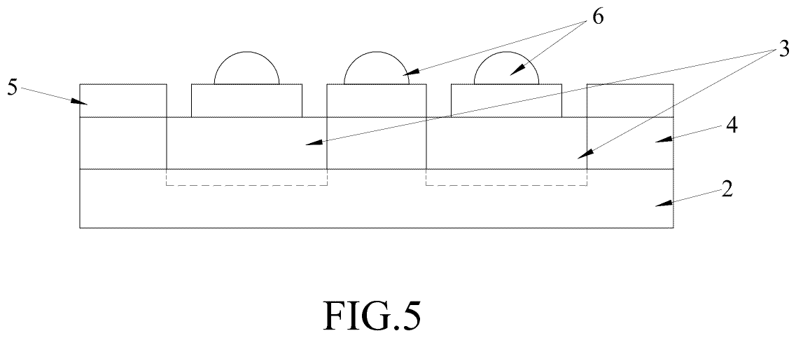

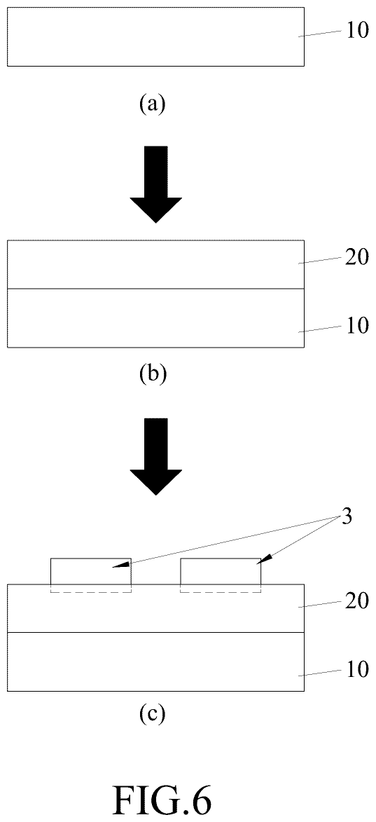

Referring to FIG. 5, an embodiment of a fan-out type packaging structure according to this disclosure includes a strain adjustment layer 2, a plurality of chips 3, an encapsulation layer 4, a redistribution layer 5 and a plurality of solder balls 6. The strain adjustment layer 2 is made of a polymer material 20 and has at least 95% laser absorbance. The plurality of chips 3 are partially embedded in the strain adjustment layer 2 and are spaced apart from each other. The encapsulation layer 4 surrounds the chips 3 and is connected to the strain adjustment layer 2. The redistribution layer 5 covers the encapsulation layer 4 and the chips 3. The plurality of solder balls 6 are disposed on the redistribution layer and are spaced apart from each other. FIGS. 6-8 show an embodiment of a method of fabricating the fan-out type packaging structure involving steps (a) to (i). It should be noted that, compared to the method as described in the background the embodiment of the method for manufacturing the fan-out type packaging structure of the present disclosure may omit the step (J). More specifically, the strain adjustment layer 2 of the present embodiment may replace the back protection layer 11 of the conventional fan-out type packaging structure 1 and prevent warpage from occurring after the laser debonding step, specific details of which will be set out in the following.

Referring to FIG. 6, the step (a) in the method of present disclosure involves providing a glass base plate 10 is provided. Subsequently, in the step (b), a layer of the polymer material 20 is hot pressed and adhered to the glass base plate 10 under temperature conditions ranging from 50° C. to 120° C. The layer of the polymer material 20 has a thickness that is at least 20 μm. Next, in the step (c), the plurality of chips 3 are heated to a working temperature which is high enough to soften the polymer material 20, so that a bottom portion of each of the chips 3 is embedded into the layer of the polymer material 20, i.e., each of the chips 3 is partially embedded in the layer of the polymer material 20. In some embodiments, the working temperature ranges between about 120° C. and 180° C. It should be especially noted that the polymer material 20 is heated by the heated chip so that rheology characteristic thereof is changed, that not only allows the heated chips 3 to adhere but also be partially embedded in the layer of the polymer material 20. This helps to increase adhesion of the chips 3.

In some embodiments, the thickness of the layer of the polymer material 20 used in step (b) ranges from 20 μm to 100 μm. In some embodiments, the polymer material 20 is an epoxy resin-based material. The epoxy resin-based material may be a liquid epoxy resin or a solid epoxy resin. In some embodiments, the epoxy resin-based material is epoxy resin copolymer. The polymer material 20 has a molecular weight between a few hundred to a few hundred thousand. Because the polymer material 20 in step (c) is heated by the heated chips 3, in order to prevent displacement of the chips 3 on a top portion of the layer of the polymer material 20 due to low dynamic viscosity of the polymer material 20, or the chips 3 not being partially embedded into the top portion of the layer of the polymer material 20 due to high dynamic viscosity of the polymer material 20, the polymer material 20 may have a dynamic viscosity ranging from 500 to 100000 poise at a temperature ranging between 120° C. and 180° C.

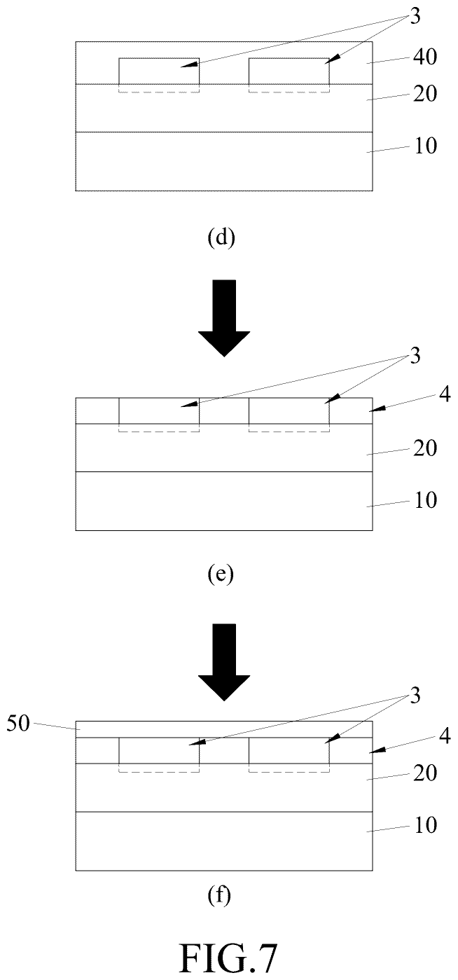

Referring to FIG. 7, in the step (d), an encapsulation material 40 is compression molded over the chips 3 and the layer of the polymer material 20, in the subsequent step (e), the encapsulation material 40 is ground to expose a top surface of each chip 3, thereby forming the encapsulation material 40 into the encapsulation layer 4, and in the next step (f), a metal layer 50 is formed over each chip 3 and the encapsulation layer 4.

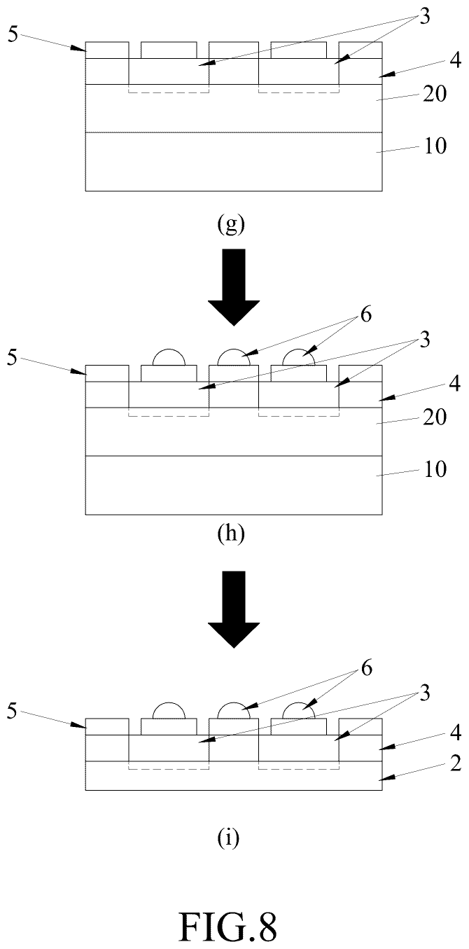

Referring to FIG. 8, in the step (g), the metal layer 50 formed in the step (f) is patterned via photolithography and etching, so as to form the metal layer 50 into the redistribution layer 5. In the subsequent step (h), the solder balls 6 are disposed on the redistribution layer 5 and are spaced apart from each other. Subsequently in the step (i), a laser (not shown) is provided and applied to the layer of the polymer material 20 adjacent to the glass base plate 10, so that the glass base plate 10 and a portion of the layer of the polymer material 20 adjacent to the glass base plate is removed by laser debonding procedure. A residue of the layer of the polymer material 20 becomes the strain adjustment layer 2. In some embodiments, the polymer material 20 (which forms the strain adjustment layer 2) has a thermal degradation temperature at 5% weight loss that ranges from 350° C. to 450° C., and the portion of the layer of the polymer material 20 that is disintegrated via the laser debonding procedure is between 5 μm and 10 μm thick. The residue of the layer of the polymer material 20 that becomes the strain adjustment layer 2 has a thickness that is no less than 10 μm. Therefore, the strain adjustment layer 2 has a thickness that is no less than 10 μm. More specifically, in some embodiments, after performing the step (i), the thickness of the strain adjustment layer 2 ranges from 10 μm to 95 μm.

In the fan-out type packaging structure according to the present disclosure, the strain adjustment layer 2 is made of the polymer material 20 having at least 95% laser absorbance so that the polymer material 20 may be debonded and a portion of the layer of the polymer material 20 may be disintegrated by the laser. The residue of the layer of the poly material 20 becomes the strain adjustment layer 2 which substitutes the back protection layer 11 of the conventional fan-out type packaging structure. This omits having to preform the step of adhering the back protection layer 11 to the chip 12, which is required for fabricating the conventional fan-out type packaging structure, and can save time and costs. Additionally, the thickness of the strain adjustment layer 2 may be adjusted to range from 10 μm to 95 μm depending on the amount of projected warpage the fan-out type packaging structure might have after fabrication, and reduce or even completely rectify the warpage. Therefore, in some embodiments, the fan-out type packaging structure has a warpage height that is less than 5 mm. It should be noted that the warpage height should be defined as the amount of warpage of a bottom surface of the fan-out type packaging structure in Euclidean space. The warpage height is measured as the difference between two points that are furthest away from each other in a height direction on the bottom surface of the fan-out type packaging structure after warpage.

It should be especially noted that the thickness of the layer of the polymer material 20 in the step (b) and the thickness of the portion of the layer of the polymer material 20 that is disintegrated in step (i) may be decided by the amount of projected warpage of the fan-out type packaging structure and would need to be adjusted accordingly, and the adjustment in thickness can be made by altering the formulation of the polymer material 20. More specifically, different formulations of epoxy resins of the polymer material 20 may have different Young's Modulus and coefficients of thermal expansion (CTE). The thickness×Young's Modulus×CTE of the polymer material 20 may be between 100 μm·GPa·ppm/° C. and 200000 μm·GPa·ppm/° C. The thickness of the layer of the polymer material 20 in the step (b) and the thickness of the portion of the layer of the polymer material 20 that is disintegrated in step (i) may be determined by the above calculating formula, and not limited the aforesaid exemplified range.

In summary of the above, in the fan-out type packaging structure according to the present disclosure, the strain adjustment layer 2 may replace the laser-debond film 101 and the back protection layer 11 in the conventional fan-out type packaging structure. The present disclosure not only solves the problem of warpage due to laser debonding procedure, thereby increasing yield rates, but also simplifies fabrication and saves costs.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cove r various arrangements included within the spirit and scope of the broadest interpretation so as to encompass all such modifications and equivalent arrangements.

What is claimed is:

1. A fan-out type packaging structure comprising:
a strain adjustment layer made of a polymer material and having at least 95% laser absorbance;
a plurality of chips partially embedded in said strain adjustment layer and being spaced apart from each other;
an encapsulation layer surrounding said chips and connected to said strain adjustment layer;
a redistribution layer covering said encapsulation layer and said chips; and
a plurality of solder balls disposed on said redistribution layer and being spaced apart from each other.

2. The fan-out type packaging structure as claimed in claim 1, wherein said strain adjustment layer has a thermal degradation temperature at 5% weight loss that ranges from 350° C. to 450° C.

3. The fan-out type packaging structure as claimed in claim 2, wherein said stain adjustment layer has a thickness that is no less than 10 μm.

4. The fan-out type packaging structure as claimed in claim 2, wherein said strain adjustment layer has a dynamic viscosity ranging from 500 and 100000 poise at a temperature between 120° C. and 180° C.

5. The fan-out type packaging structure as claimed in claim 4, wherein said strain adjustment layer has a thickness that is no less than 10 μm.

6. The fan-out type packaging structure as claimed in claim 4, wherein said fan-out type packaging structure has a warpage height that is less than 5 mm.

7. The fan-out type packaging structure as claimed in claim 6, wherein said strain adjustment layer has a thickness that is no less than 10 μm.

8. The fan-out type packaging structure as claimed in claim 1, wherein said strain adjustment layer has a thickness that is no less than 10 μm.

9. The fan-out type packaging structure as claimed in claim 8, wherein said thickness of said strain adjustment layer ranges from 10 μm to 95 μm.

10. The fan-out type packaging structure as claimed in claim 1, wherein said polymer material of said strain adjustment layer is an epoxy resin-based material.

11. The fan-out type packaging structure as claimed in claim 10, wherein said epoxy resin-based material is liquid epoxy resin.

12. The fan-out type packaging structure as claimed in claim 10, wherein said epoxy resin-based material is solid epoxy resin.

13. The fan-out type packaging structure as claimed in claim 10, wherein said epoxy resin-based material is epoxy resin copolymer.
